(19) United States
(12) Patent Application Publication
(10) Pub. No.: US 2015/0260779 A1
(43) Pub. Date: Sep. 17, 2015

(54) SEMICONDUCTOR DEVICE

(71) Applicant: KABUSHIKI KAISHA TOSHIBA, Minato-ku (JP)

(72) Inventor: Masahiro KAMOSHIDA, Yokohama-Shi (JP)

(73) Assignee: KABUSHIKI KAISHA TOSHIBA, Minato-ku (JP)

(21) Appl. No.: 14/335,235

(22) Filed: Jul. 18, 2014

Related U.S. Application Data
(60) Provisional application No. 61/951,821, filed on Mar. 12, 2014.

(51) Int. Cl. G01R 31/26; G01R 31/28

(52) U.S. Cl. CPC G01R 31/26; G01R 31/28

(57) ABSTRACT

The semiconductor device according to the present embodiment comprises a plurality of monitor units monitoring characteristics of an element. Each of the monitor units comprises the element, a control/monitor node, a switch, and a selection controller. The control/monitor node transmits a control signal for controlling the monitor units, and transmits a characteristic signal for indicating electrical characteristics of the element. The switch is connected between the element and a control/monitor node. The selection controller selectively controls the switch upon reception of the control signal. A wire of the control/monitor node of the plurality of monitor units is commonalized.

### CROSS REFERENCE TO RELATED APPLICATIONS

This application is based upon and claims the benefit of priority from the prior U.S. Provisional Patent Application No. 61/951,821, filed on Mar. 12, 2014, the entire contents of which are incorporated herein by reference.

### FIELD

The embodiments of the present invention relate to a semiconductor device.

### BACKGROUND

Conventionally, in order to monitor electrical characteristics of elements formed on a semiconductor chip on a trial basis, a test circuit is formed in a wafer area such as a dicing area in which no chip is provided. When such a test circuit is formed in a wafer area such as a dicing area in which no chip is provided, because the test circuit is formed in an area that is separated from the semiconductor chip, the dimension of an element forming area of the semiconductor chip is not decreased. However, because the test circuit is arranged outside of the semiconductor chip, there is a case where the characteristics of the test circuit are different from those of elements of the semiconductor chip. Furthermore, because the wafer area such as a dicing area in which no chip is provided is relatively narrow, it is difficult to increase the number of test circuits.

It is conceivable that test circuits are formed in a semiconductor chip. However, in this case, the dimension of the element forming area of the semiconductor chip is decreased by not only the test circuits but also by a large number of wires for connecting these test circuits. Furthermore, when a plurality of test circuits are arranged on the semiconductor chip in a dispersed manner, wires need to be drawn in the semiconductor chip. Therefore, this arrangement further decreases the dimension of the element forming area of the semiconductor chip. In order to reduce such area penalties as much as possible, it is inevitably necessary to reduce the number of test circuits.

### BRIEF DESCRIPTION OF THE DRAWINGS

FIG. 1 is a block diagram showing a configuration example of a semiconductor device 1 according to a first embodiment;

FIG. 2 is a block diagram showing a configuration example of the monitor unit MU according to the first embodiment;

FIGS. 3A to 3C are block diagrams showing an internal configuration of the selection control circuit 10 according to the first embodiment;

FIG. 4 is a timing diagram showing an example of an operation of the semiconductor device 1 according to the first embodiment;

FIG. 5 is a block diagram showing a configuration example of the selection control circuit 10 according to a second embodiment;

FIG. 6 shows truth values of logical operations performed by the logical circuit 26;

FIG. 7 is a timing diagram showing an example of an operation of the semiconductor device 1 according to the second embodiment;

FIG. 8 is a block diagram showing a configuration example of the selection control circuit 10 in a case where one monitor unit MU includes a plurality of elements 30 and a plurality of switches 20; and

FIG. 9 is a block diagram showing another configuration example of the selection control circuit 10 in a case where one monitor unit MU includes a plurality of elements 30 and a plurality of switches 20.

### DETAILED DESCRIPTION

Embodiments will now be explained with reference to the accompanying drawings. The present invention is not limited to the embodiments.

The semiconductor device according to the present embodiment comprises a plurality of monitor units monitoring characteristics of an element. Each of the monitor units comprises the element, a control/monitor node, a switch, and a selection controller. The control/monitor node transmits a control signal for controlling the monitor units, and transmits a characteristic signal for indicating electrical characteristics of the element. The switch is connected between the element and a control/monitor node. The selection controller selectively controls the switch upon reception of the control signal. A wire of the control/monitor node of the plurality of monitor units is commonalized.

### First Embodiment

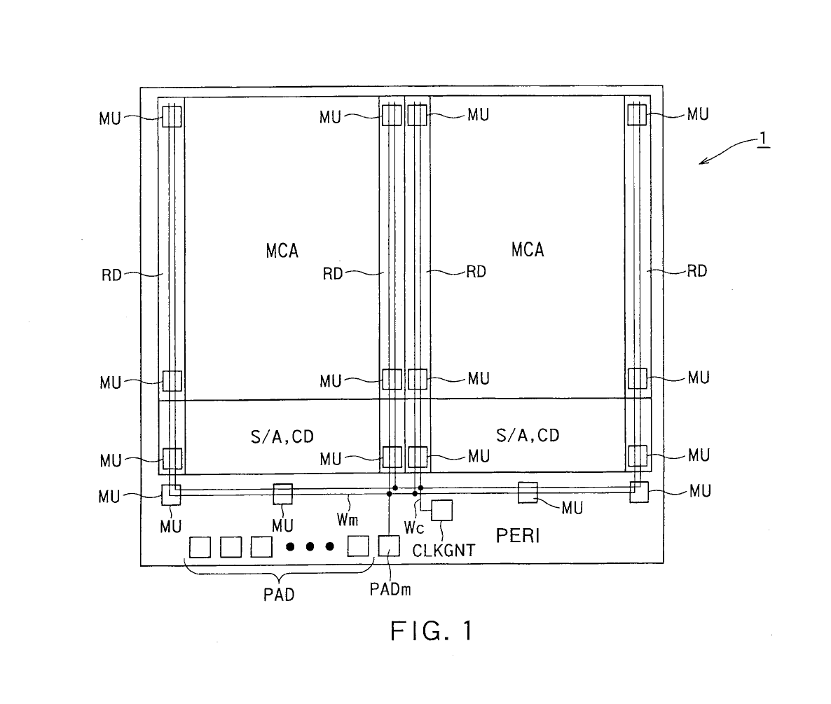

FIG. 1 is a block diagram showing a configuration example of a semiconductor device 1 according to a first embodiment. The semiconductor device 1 is a memory chip, for example, and includes a memory cell array MCA and a peripheral circuit area PERI. A sense amplifier block S/A, a column decoder block CD, a row decoder block RD and the like are formed around the memory cell array MCA. A circuit that controls the memory cell array MCA, pads and the like are formed around the peripheral circuit area PERI. The first embodiment is not limited to a memory, and can be also applied to other semiconductor devices.

The semiconductor device 1 further includes monitor units MU, a clock wire Wc, a monitor/control wire Wm, a clock generation circuit CLKGNT, and a pad PADm.

The monitor units MU are provided for monitoring electrical characteristics of elements formed in the semiconductor device 1. The monitor unit MU can be also referred to as “test circuit” or “TEG (Test Element Group)”. The monitor unit MU is formed in the row decoder block RD or the peripheral circuit area PERI. A plurality of monitor units MU are arranged in the semiconductor device 1 in a dispersed manner. With this arrangement, the semiconductor device 1 can monitor the state of the elements in respective areas in a chip highly accurately.

The clock wire Wc transmits a clock signal output from the clock generation circuit CLKGNT to the monitor units MU. A clock signal CLK is used ubiquitously in a semiconductor chip in a normal operation. Therefore, the clock wire Wc is arranged in many positions in the semiconductor chip regardless of the arrangement of the monitor units MU. Accordingly, if a plurality of monitor units MU are arranged in the semiconductor chip in a dispersed manner, extension of the clock wire Wc is hardly required.

A control/monitor wire Wm transmits a control signal input from the pad PADm to the monitor units MU, and also transmits a monitor output signal (characteristic signal) from the monitor units MU to the pad PADm. Therefore, the control/monitor wire Wm is extended to a position where each of the monitor units MU is arranged.

The control signal is a signal for controlling the monitor unit MU, and including selection information and a monitor mode signal. The selection information is a signal for selecting the monitor unit MU or a switch 20 and controlling the selected element. It can be also understood that the selection information selects an element 30 as a monitoring target by selecting the monitor unit MU or the switch 20. The monitor mode signal is a trigger signal for causing the semiconductor device 1 to shift to a monitor mode. The monitor mode is a mode of monitoring electrical characteristics of the element in the monitor unit MU on a trial basis. The monitor output signal is a signal for indicating electrical characteristics of an element as a monitoring target.

As shown in FIG. 1, not only the clock wire Wc but also the control/monitor wire Wm is communalized (shared) with respect to a plurality of monitor units MU. For example, the control/monitor wire Wm is formed of one wire. That is, the semiconductor device 1 according to the first embodiment transmits a control signal for controlling the monitor units MU and a monitor output signal for indicating element characteristics via the same (common) control/monitor wire Wm. Therefore, the monitor units MU are configured as follows.

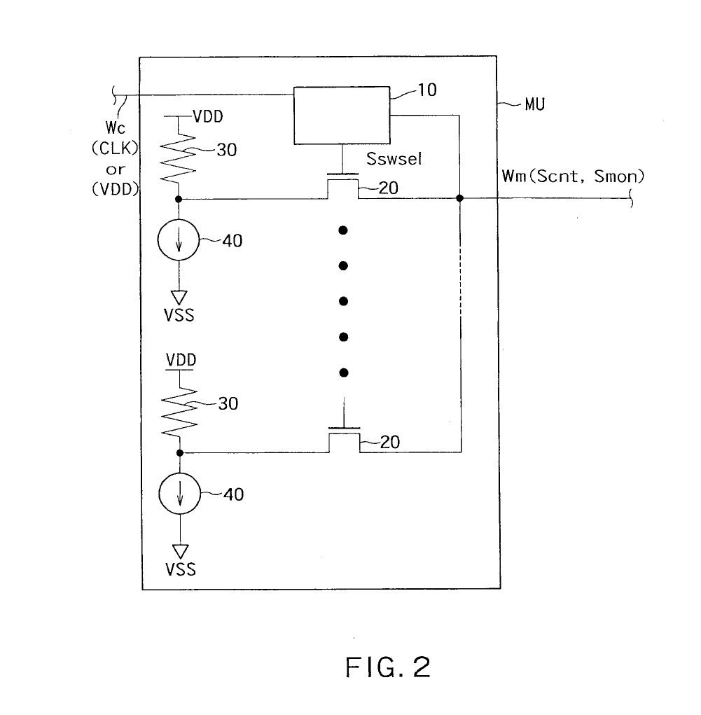

FIG. 2 is a block diagram showing a configuration example of the monitor unit MU according to the first embodiment. The monitor unit MU includes a selection control circuit 10, the switches 20, and the elements 30.

The selection control circuit 10 receives the clock signal CLK via the clock wire Wc, synchronizes with the clock signal CLK, and receives a control signal Scnt via the control/monitor wire Wm. Subsequently, the selection control circuit 10 selectively controls ON and OFF of the switch 20 by a switch selection signal Sswsel based on the control signal Scnt.

The switch 20 is connected between the element 30 and the control/monitor wire Wm, and electrically connects or disconnects the element 30 to or from the control/monitor wire Wm. The switch 20 is under control of the switch selection signal Sswsel, and is in an off-state when it is unselected and in an on-state when selected. With this configuration, when it is selected, the switch 20 electrically connects the element 30 to the control/monitor wire Wm.

The element 30 can be an arbitrary element formed in the semiconductor device 1, such as a resistor, a capacitor, a transistor, or a diode. In FIG. 2, as an example of the element 30, a resistor is shown. A current source 40 passes a constant current to the elements 30.

The number of the elements 30 and that of the switches 20 formed in one monitor unit MU can be one or plural.

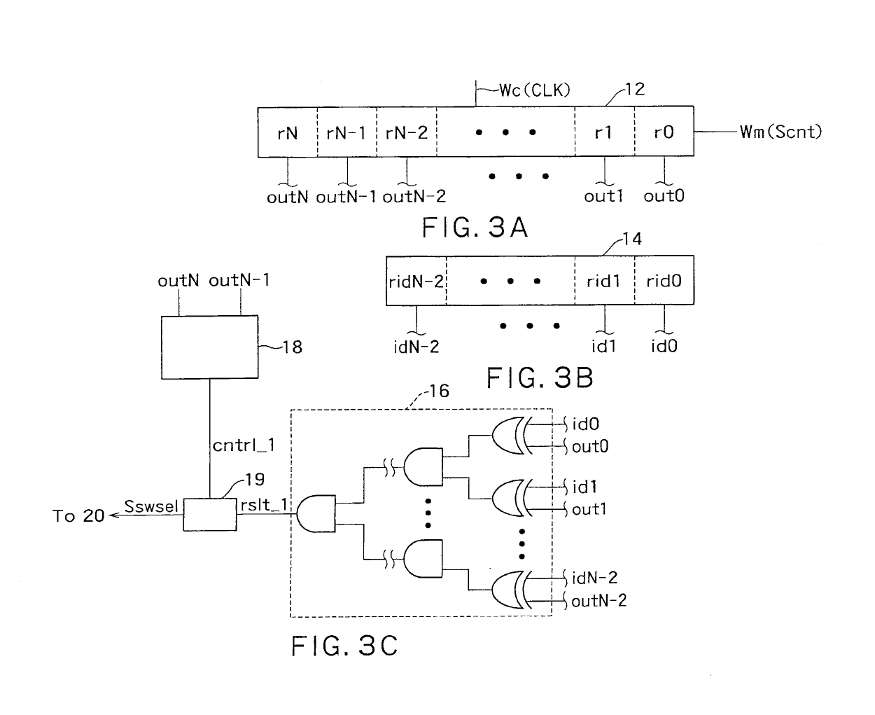

FIGS. 3A to 3C are block diagrams showing an internal configuration of the selection control circuit 10 according to the first embodiment. The selection control circuit 10 includes a shift register 12 as a control-signal storage part, an ID storage part 14 as an identification-information storage part, a logic determination circuit 16 as a determination part, a mode identification circuit 18, and a determination-result storage part 19.

The shift register 12 shown in FIG. 3A is connected to the clock wire Wc and the control/monitor wire Wm, and receives the clock signal CLK and the control signal Scnt. The shift register 12 includes registers r0 to rN, each of which can retain a digital value for every one bit, and stores therein a digital value (a pulse signal) of the control signal Scnt according to the timing of the clock signal CLK.

For example, upon reception of a first pulse clk1 of the clock signal CLK, the shift register 12 retains the digital value (logical high or logical low) of the control signal Scnt in the register r0. Upon reception of a second pulse clk2 of the clock signal Scnt, the shift register 12 shifts the digital value corresponding to the pulse clk1 from the register r0 to the register r1. The shift register 12 then retains the digital value of the control signal Scnt corresponding to the pulse clk2 in the register r0. Similarly, upon reception of a third pulse clk3 of the clock signal CLK, the shift register 12 shifts the digital value corresponding to the pulse clk1 from the register r1 to the register r2, and the digital value corresponding to the pulse clk2 from the register r0 to the register r1. Subsequently, the shift register 12 retains the digital value of the control signal Scnt corresponding to the pulse clk3 in the register r0. In this manner, the shift register 12 stores the digital value of the control signal in the register r0 each time the shift register 12 receives the digital value, and the digital value stored before is respectively shifted to the register of the next stage. With this configuration, the shift register 12 can store a digital value of the control signal Scnt of N+1 digit number (N is an integer). Digital values stored in the registers r0 to rN are output from outputs out0 to outN.

In this example, digital values (out0 to outN−2) of registers r0 to rN−2 among the control signal of N+1 digit number are selection information, and digital values (outN−1 and outN) of the registers rN−1 and rN are monitor mode signals. As described above, the selection information selects the monitor unit MU or the switch 20, and with this selection, the selection information becomes information for selecting the element 30 as a monitoring target. By entering a monitor mode, the monitor unit MU can effectively output electrical characteristics of the element 30 as a monitor output signal Smon via a selected switch 20.

The ID storage part 14 shown in FIG. 3B stores therein identification information (hereinafter, also “ID information”) of the monitor unit MU or the switch 20. The ID storage part 14 stores therein predetermined ID information. The ID information is capable of specifying the monitor unit MU, the switch 20, and the element 30, and the ID information is different in each one of the monitor units MU, the switches 20, and the elements 30. Similarly to the selection information (out0 to outN−2), the ID information is a digital value of N−1 digit number. Accordingly, the selection information and the ID information can be comparable to each other. The ID storage part 14 includes registers rid0 to ridN−2, each of which can retain a digital value for every one bit, and stores therein a digital value of the ID information. The ID storage part 14 outputs id0 to idN−2 as the ID information.

When the monitor unit MU includes only one switch 20, the ID information can be regarded as a signal for identifying the monitor unit MU, or can be regarded as a signal for identifying the switch 20 or the element 30. On the other hand, as shown in FIG. 2, when the monitor unit MU includes a plurality of switches 20 and a plurality of elements 30, it is not sufficient if the ID information identifies only the monitor unit MU, and the ID information needs to identify the switch 20 or the element 30. Therefore, in this case, the ID information is a signal for identifying the switch 20 or the element 30.

The logic determination circuit 16 shown in FIG. 3C inputs the selection information (out0 to outN−2) from the shift register 12 and the ID information (id0 to idN−2) from the ID storage part 14, and determines whether these pieces of information match each other. For example, an XOR gate of the logic determination circuit 16 compares respective bits of the selection information (out0 to outN−2) and the ID information (in to idN−2), and outputs logical high when outk and idk (k=0 to N−1) are equal and outputs logical low when these pieces of information are different. Subsequently, by performing an AND operation on the output of the XOR gate, a determination result rslt_1 can be obtained. When the selection information (out0 to outN−2) and the ID information (id0 to idN−2) match each other, the determination result rslt_1 becomes logical high, and when the selection information (out0 to outN−2) and the ID information (id0 to idN−2) do not match each other, the determination result rslt_1 becomes logical low. In this manner, the logic determination circuit 16 can determine a match or mismatch of the selection information (out0 to outN−2) and the ID information (id0 to idN−2).

The determination-result storage part 19 stores therein the determination result rslt_1 output from the logic determination circuit 16 and retains the output determination result rslt_1. The determination-result storage part 19 outputs the switch selection signal Sswsel based on a mode signal cntrl_1.

The mode identification circuit 18 receives the monitor mode signals (outN−1 and outN) from the shift register 12. When the monitor mode signals are a predetermined digital value, the mode identification circuit 18 determines that these signals are in a monitor mode, and then sets the mode signal cntrl_1 to be logical high and activates the determination-result storage part 19. With this process, the determination-result storage part 19 receives an input of the determination result rslt_1. On the other hand, when these monitor mode signals are not a predetermined digital value, the mode identification circuit 18 determines that these signals are not in a monitor mode, and then maintains the mode signal cntrl_1 to be logical low and deactivates the determination-result storage part 19. With this process, when the mode signal cntrl_1 is logical high, the determination-result storage part 19 takes in the determination result rslt_1, and stores therein the determination result rslt_1 when the mode signal cntrl_1 is changed from logical high to logical low. Thereafter, the determination-result storage part 19 keeps outputting the stored determination result rslt_1 as the switch selection signal Sswsel.

As described above, the semiconductor device 1 can shift to a monitor mode based on the monitor mode signals (outN−1 and outN) of the control signal Scnt and select the monitor unit MU or the switch 20 based on the selection information (out0 to outN−2). The selection control circuit 10 can cause the selected switch 20 to be conductive while keeping unselected switches 20 in a nonconductive state. With this configuration, the monitor unit MU can output electrical characteristics of the selected switch 20 and those of the element 30 via a common control/monitor wire Wm. When the selection information and the ID information do not match each other, based on the determination result rslt_1, the selection control circuit 10 recognizes that a corresponding switch 20 is not selected based on the determination result rslt_1, and maintains the switches to be nonconductive.

As shown in FIG. 2, when one monitor unit MU includes a plurality of elements 30 and a plurality of switches 20 that respectively correspond to the elements 30, the shift register 12 and the mode identification circuit 18 shown in FIGS. 3A and 3C can be common to the switches 20. However, the ID storage part 14, the logic determination circuit 16, and the determination-result storage part 19 shown in FIG. 3B and FIG. 3C need to be provided as these units respectively correspond to the switches 20. That is, when one monitor unit MU includes m elements 30 and m switches 20 (m is an integer), while the number of the shift register 12 and the mode identification circuit 18 can be one, the respective numbers of the ID storage parts 14, the logic determination circuit 16, and the determination-result storage part 19 to be provided need to be m.

In this case, each of the plurality of ID storage parts 14 stores therein identification information of respectively corresponding one of the switches 20 (or the elements 30). The plurality of logic determination circuits 16 compare each of the identification information of the plurality of switches 20 (or the elements 30) to each of the selection information. The determination-result storage part 19 stores therein a plurality of determination results corresponding to the plurality of switches 20 (or the elements 30), and causes a selected one of the switches 20 to be conductive according to the determination results.

In this manner, one monitor unit MU can include a plurality of elements 30 and a plurality of switches 20.

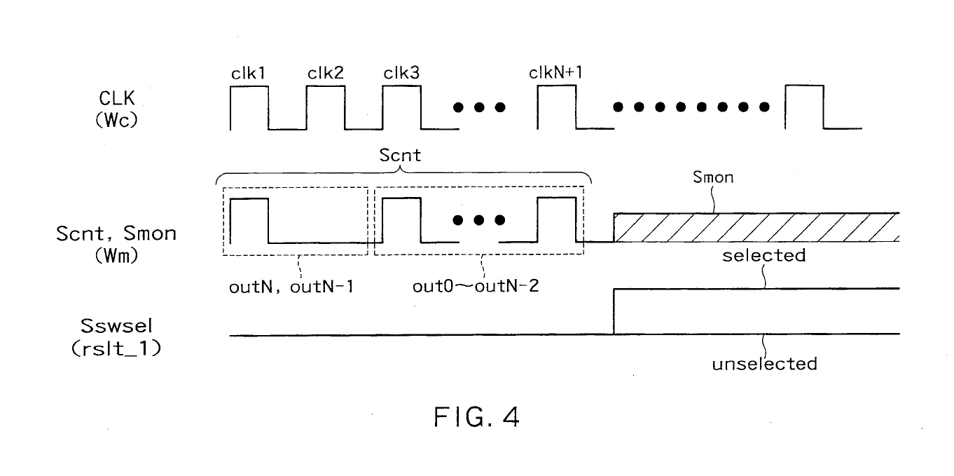

FIG. 4 is a timing diagram showing an example of an operation of the semiconductor device 1 according to the first embodiment. The clock signal CLK outputs a pulse signal at a certain interval. In FIG. 4, the clock signal CLK is sent to the shift register 12 via the clock wire Wc in the order of the pulses clk1, clk2, clk3, to a pulse clkN+1.

The control signal Scnt synchronizes with the clock signal CLK and is stored in the shift register 12 via the control/monitor wire Wm. In a normal operation of the semiconductor device 1, the control signal Scnt is maintained to be logical low and does not include any pulse. At this time, the monitor unit MU and the control/monitor wire Wm are not activated.

On the other hand, when the control signal Scnt includes a pulse (logical high), the selection controller 10 handles the control signal Scnt as a monitor mode signal using the pulse signal of the included pulse as a trigger. For example, when the control signal Scnt becomes logical high at a certain pulse clk1 of the clock signal CLK, the selection controller 10 handles the control signal Scnt corresponding to the pulses clk1 and clk2 as the monitor mode signals outN and outN−1. In FIG. 4, when the monitor mode signals outN and outN−1 are logical high and logical low, respectively, the mode identification circuit 18 shown in FIG. 3C raises the mode signal cntrl_1 to be logical high and activates the determination-result storage part 19. As the determination-result storage part 19 is activated, the semiconductor device 1 enters a monitor mode. The monitor mode signal can be a control signal Scnt that corresponds to three or more pulses of the clock signal CLK.

As described above, when the mode signal cntrl_1 becomes logical high and then becomes logical low, the determination-result storage part 19 temporarily stores therein the determination result rslt_1. Thereafter, regardless of the logic of the mode signal cntrl_1, the determination-result storage part 19 keeps outputting the stored determination result rslt_1 as the switch selection signal Sswsel.

The control signal Scnt to be input after the monitor mode signals outN and outN−1 is stored in the shift register 12 as the selection information (out0 to outN−2). The pieces of selection information (out0 to outN−2) respectively correspond to the pulses clk3 to clkN+1 of the clock signal CLK, and are input to the shift register 12 in the order of outN−2, outN−3, to out0.

The digit numbers (bit numbers) of the monitor mode signal and the selection information are set in advance, and thus the selection control circuit 10 outputs the monitor output signal Smon via the common control/monitor wire Wm after receiving the monitor mode signal and the selection information (that is, the control signal Scnt) via the control/monitor wire Wm.

As described above, when the selection information and the ID information match each other, the selection controller 10 raises the switch selection signal Sswsel, and causes the corresponding switch 20 to be conductive so as to connect the element 30 to the control/monitor wire Wm. With this process, the monitor unit MU outputs electrical characteristics of the element 30 as the monitor output signal Smon to outside of the semiconductor device 1 via the control/monitor wire Wm.

On the other hand, when the selection information and the ID information do not match each other, the selection controller 10 does not raise the switch selection signal Sswsel, and maintains the corresponding switch 20 to be nonconductive. With this configuration, it is possible to suppress collisions of the monitor output signals Smon of a plurality of elements 30 on the control/monitor wire Wm.

Thereafter, when a measurement is finished, it suffices that the power supply of the semiconductor device 1 is turned off. With this process, the shift register 12 and the determination-result storage part 19 can be reset.

In this manner, the semiconductor device 1 according to the first embodiment transmits the control signal Scnt and the monitor output signal Smon via the same (common) control/monitor wire Wm. Furthermore, because the selection control circuit 10 is provided in each of a plurality of monitor units MU, the control/monitor wire Wm can be commonalized with respect to the plurality of monitor units MU. With this configuration, one control/monitor wire Wm is sufficient enough to each of the monitor units MU, as well as sufficient enough to the plurality of monitor units MU. Therefore, when a plurality of monitor units MU are arranged in a semiconductor chip in a dispersed manner as shown in FIG. 1, it is only necessary to add or extend one control/monitor wire Wm. That is, as one control/monitor wire Wm is wired to the monitor units MU, the semiconductor device 1 can perform selection of the monitor unit MU, the switch 20, and the element 30 and monitoring of the element 30 at the same time. Because it is only necessary to add or extend one control/monitor wire Wm, even if the number of the monitor units MU arranged in a semiconductor chip is increased, the dimension of the element forming area of the semiconductor chip is not decreased too much. That is, even if the number of the monitor units MU is increased, area penalties are minimized.

As described above, the clock wire Wc is arranged in many positions in a semiconductor chip regardless of the arrangement of the monitor units MU. Therefore, even if the number of the monitor units MU is increased, extension of the clock wire Wc is hardly required.

### Second Embodiment

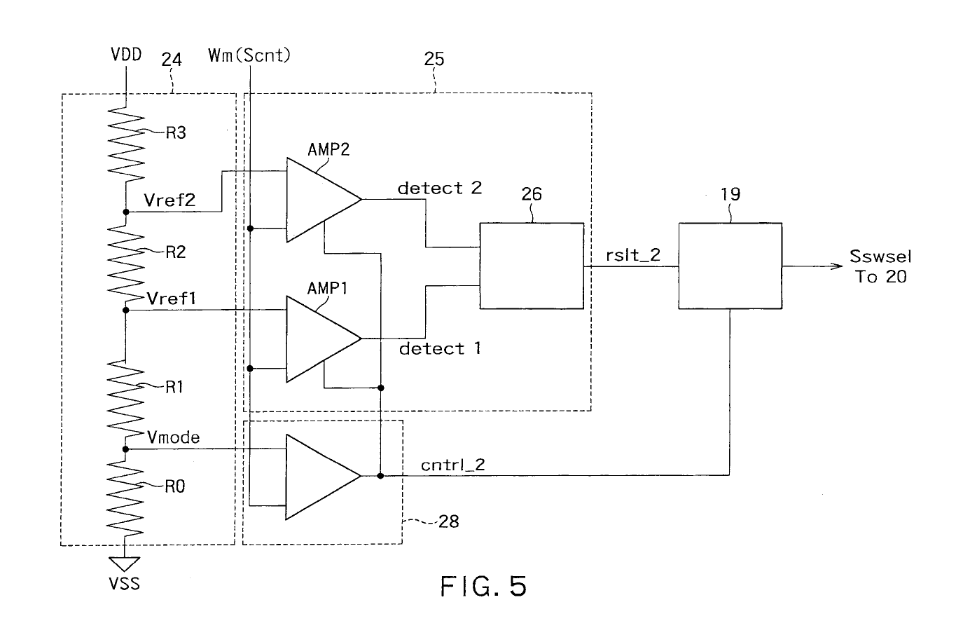

FIG. 5 is a block diagram showing a configuration example of the selection control circuit 10 according to a second embodiment. While the control signal in the first embodiment is a digital value, the control signal in the second embodiment is an analog value. Therefore, in the second embodiment, to determine the control signal, a reference signal expressed by an analog value is used instead of ID information. The basic configuration of the semiconductor device 1 according to the second embodiment can be identical to the configurations shown in FIGS. 1 and 2. However, the clock generation signal CLKGNT shown in FIG. 1 functions as a VDD generation circuit or a pad for inputting a VDD. In the second embodiment, the wires Wc shown in FIGS. 1 and 2 are wires for transmitting a high-level voltage source VDD.

The selection control circuit 10 according to the second embodiment includes a switch-reference signal generation unit 24 or a mode-reference signal generation unit 24 (hereinafter, both are simply referred to as “signal generation unit 24”), a determination part 25, the determination-result storage part 19, and a mode comparator 28.

The signal generator 24 includes resistors R0 to R3. The resistors R0 to R3 are connected in series between the voltage source VDD and a low-level voltage source VSS to constitute a resistor string. The resistors R0 to R3 performs resistance-division on the high-level voltage source VDD to generate switch reference signals Vref1 and Vref2 and a mode reference signal Vmode. For example, the mode reference signal Vmode is output from a node between the resistors R0 and R1. The switch reference signal Vref1 is output from a node between the resistors R1 and R2. The switch reference signal Vref2 is output from a node between the resistors R2 and R3. Voltage levels of the signals Vmode, Vref1, and Vref2 have a relationship of Vmode<Vref1<Vref2. Vref1 and Vref2 represent a switch reference signal or a voltage value thereof. Vmode represents a mode reference signal or a voltage value thereof.

The mode reference signal Vmode is a signal as a reference when the semiconductor device 1 shifts to a monitor mode. When a voltage Vcnt (hereinafter, also “control voltage Vcnt”) of the control signal Scnt from the control/monitor wire Wm exceeds the mode reference signal Vmode, the semiconductor device 1 shifts to a monitor mode.

The switch reference signals Vref1 and Vref2 are signals as a reference when the monitor unit MU, the switch 20, or the element 30 is selected. When the control voltage Vcnt is in a range between the voltage of the switch reference signal Vref1 and the voltage of the switch reference signal Vref2, the switch 20 is set to be conductive.

The determination part 25 includes operation amplifiers AMP1 and AMP2 and a logic circuit 26. The operation amplifier AMP1 receives the switch reference signal Vref1 and the control signal Scnt, amplifies the voltage difference between voltages of these signals, and outputs the amplified voltage difference as a detection result detect1. When the control voltage Vcnt is lower than the switch reference voltage Vref1, the operation amplifier AMP1 sets the detection result detect1 to be logical low, for example. When the control voltage Vcnt is higher than the switch reference voltage Vref1, the operation amplifier AMP1 inverts the logic of the detection result detect1 and sets the detection result detect1 to be logical high, for example.

The operation amplifier AMP2 receives the switch reference signal Vref2 and the control signal Scnt, amplifies the voltage difference between voltages of these signals, and outputs the amplified voltage difference as a detection result detect2. When the control voltage Vcnt is lower than the switch reference voltage Vref2, the operation amplifier AMP2 sets the detection result detect2 to be logical low, for example. When the control voltage Vcnt is higher than the switch reference voltage Vref2, the operation amplifier AMP2 inverts the logic of the detection result detect2 and sets the detection result detect2 to be logical high, for example.

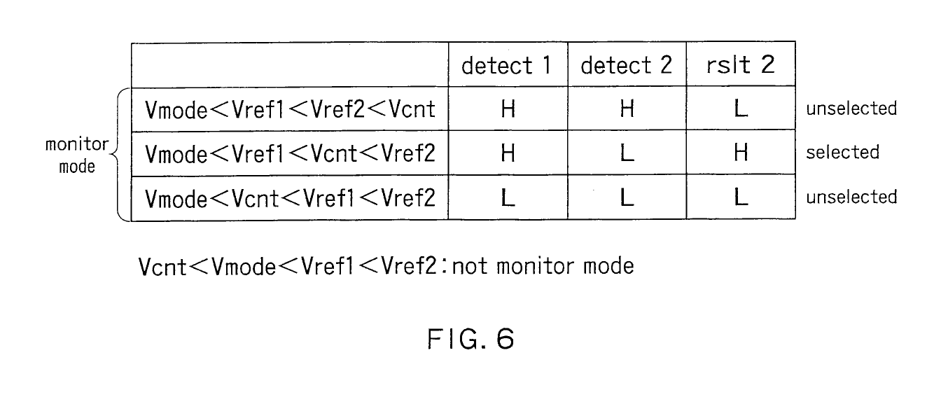

The logic circuit 26 receives the detection results detect1 and detect2 from outputs of the operation amplifiers AMP1 and AMP2, and performs logic operations on the detection results detect1 and detect2. The logic circuit 26 outputs an operation result (a determination result rslt_2) of the detection results detect1 and detect2. The logic operations performed by the logic circuit 26 are explained below with reference to FIG. 6.

The determination-result storage part 19 stores therein the determination result rslt_2 from the logic circuit 26 based on a mode signal cntrl_2, and holds the determination result rslt_2. For example, when the mode signal cntrl_2 is raised to be logical high, the determination-result storage part 19 receives the determination result rslt_2, and when the mode signal cntrl_2 falls to be logical low, the determination-result storage part 19 holds and outputs the determination result rslt_2. Thereafter, the determination-result storage part 19 keeps holding the logic of the determination result rslt_2. When the latch state of the determination-result storage part 19 is reset, it is only necessary to turn off the power supply of the semiconductor device 1.

The mode comparator 28 compares the voltage of the mode reference signal Vmode and the control voltage Vcnt. When the control voltage Vcnt is higher than the mode reference voltage Vmode, the mode comparator 28 determines that the semiconductor device 1 is in a monitor mode, and then sets the mode signal cntrl_2 to be logical high and activates the operation amplifiers AMP1 and AMP2 and the determination-result storage part 19. With this process, the determination-result storage part 19 receives the determination result rslt_2. On the other hand, when the control voltage Vcnt is lower than the mode reference voltage Vmode, the mode comparator 28 determines that the semiconductor device 1 is not in a monitor mode, and then maintains the mode signal cntrl_2 to be logical low and causes the operation amplifiers AMP1 and AMP2 and the determination-result storage part 19 to be deactivated. With this process, when the mode signal cntrl_2 is logical high, the determination-result storage part 19 takes in the determination result rslt_2, and stores therein the determination result rslt_2 when the mode signal cntrl_2 is changed from logical high to logical low. Thereafter, the determination-result storage part 19 keeps outputting the stored determination result rslt_2 as the switch selection signal Sswsel. In this manner, the determination-result storage part 19 outputs the switch selection signal Sswsel based on the mode reference signal Vmode. Also in the second embodiment, the control signal Scnt can be used for selection of the monitor mode as well as selection of the switch 20.

FIG. 6 shows truth values of logical operations performed by the logical circuit 26. First, when the control voltage Vcnt is lower than the mode reference voltage Vmode, the semiconductor device 1 is not in a monitor mode. At this time, the determination-result storage part 19 invalidates the determination result rslt_2 and maintains the switch 20 to be nonconductive.

When the control voltage Vcnt exceeds the mode reference voltage Vmode, the semiconductor device 1 enters a monitor mode.

In the monitor mode, when the control voltage Vcnt is lower than the switch reference voltages Vref1 and Vref2, both the detection results detect′ and detect2 are logical low, and the logical circuit 26 outputs logical low as the determination result rslt_2. At this time, the selection control circuit 10 having received the control signal Scnt is in a nonselective state.

When the control voltage Vcnt is higher than the switch reference voltage Vref1 and is lower than the switch reference voltage Vref2, the detection results detect1 and detect2 are logical high and logical low, respectively. The logical circuit 26 outputs logical high as the determination result rslt_2. At this time, the selection control circuit 10 having received the control signal Scnt is in a selective state.

When the control voltage Vcnt is higher than the switch reference voltages Vref1 and Vref2, both the detection results detect1 and detect2 are logical high, and the logical circuit 26 outputs logical low as the determination result rslt_2. At this time, the selection control circuit 10 having received the control signal Scnt is in a nonselective state.

As described above, when the control voltage Vcnt is in a range between the switch reference voltages Vref1 and Vref2, the selection control circuit 10 can recognize that the circuit itself has been selected.

The switch reference voltages Vref1 and Vref2 as ID information are information capable of specifying the monitor unit MU, the switch 20, or the element 30, and this information is different in each one of the monitor units MU, the switches 20, and the elements 30. It is preferable that voltage ranges between the switch reference voltages Vref1 and Vref2 do not overlap in each one of the monitor units MU, the switches 20, and the elements 30.

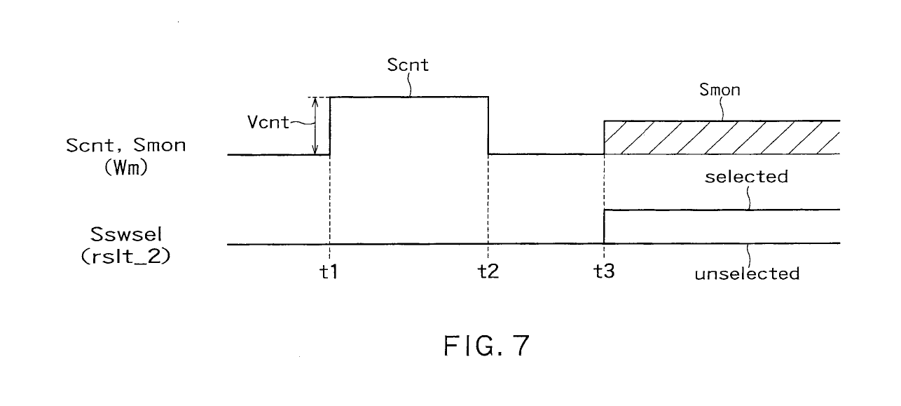

As described above, the selection control circuit 10 according to the second embodiment generates the switch reference signals Vref1 and Vref2, and then compares the control signal Scnt and the switch reference signals Vref1 and Vref2. Subsequently, the selection control circuit 10 causes the switch 20 to be conductive according to the voltage level of the control signal Scnt. After the switch 20 has become conductive, the monitor unit MU outputs the monitor output signal (characteristic signal) Smon via the control/monitor wire Wm. More details of operations of the selection control circuit 10 are explained below with reference to FIG. 7.

FIG. 7 is a timing diagram showing an example of an operation of the semiconductor device 1 according to the second embodiment.

First, before a time point t1, the control voltage Vcnt is lower than the mode reference voltage Vmode, and the semiconductor device 1 is not in a monitor mode.

At the time point t1, when the control voltage Vcnt exceeds the mode reference voltage Vmode, the semiconductor device 1 enters a monitor mode. By a comparison between the control voltage Vcnt and the switch reference voltages Vref1 and Vref2, the monitor unit MU, the switch 20, or the element 30 is selected. In this manner, as described above, the control voltage Vcnt (an analog value) is used for selection of the monitor mode as well as selection of the switch 20.

At a time point t2, when the control signal Scnt falls, the determination-result storage part 19 latches and holds the logic of the determination result rslt_2. Thereafter, the determination-result storage part 19 maintains the latch state regardless of how the logic of the determination result rslt_2 is changed.

When the control voltage Vcnt is in a range between the switch reference voltages Vref1 and Vref2, the selection controller 10 raises the switch selection signal Sswsel, causes the corresponding switch 20 to be conductive, and connects the element 30 to the control/monitor wire Wm. With this process, the monitor unit MU outputs electrical characteristics of the element 30 as the monitor output signal Smon to outside of the semiconductor device 1 via the control/monitor wire Wm.

On the other hand, when the control voltage Vcnt is not in a range between the switch reference voltages Vref1 and Vref2, the selection control circuit 10 does not raise the switch selection signal Sswsel, and maintains the corresponding switch 20 to be nonconductive. With this configuration, it is possible to suppress collisions of the monitor output signals Smon of a plurality of elements 30 on the control/monitor wire Wm.

Thereafter, when a measurement is finished, it suffices that the power supply of the semiconductor device 1 is turned off. With this process, the determination-result storage part 19 can be reset.

In this manner, similarly to the first embodiment, the semiconductor device 1 according to the second embodiment can transmit the control signal Scnt and the monitor output signal Smon via the same (common) control/monitor wire Wm. Furthermore, because the selection control circuit 10 is provided in each of a plurality of monitor units MU, the control/monitor wire Wm can be commonalized with respect to the plurality of monitor units MU. Therefore, although using an analog value as the control signal Scnt, the second embodiment can obtain effects identical to those of the first embodiment.

### Modification of Second Embodiment

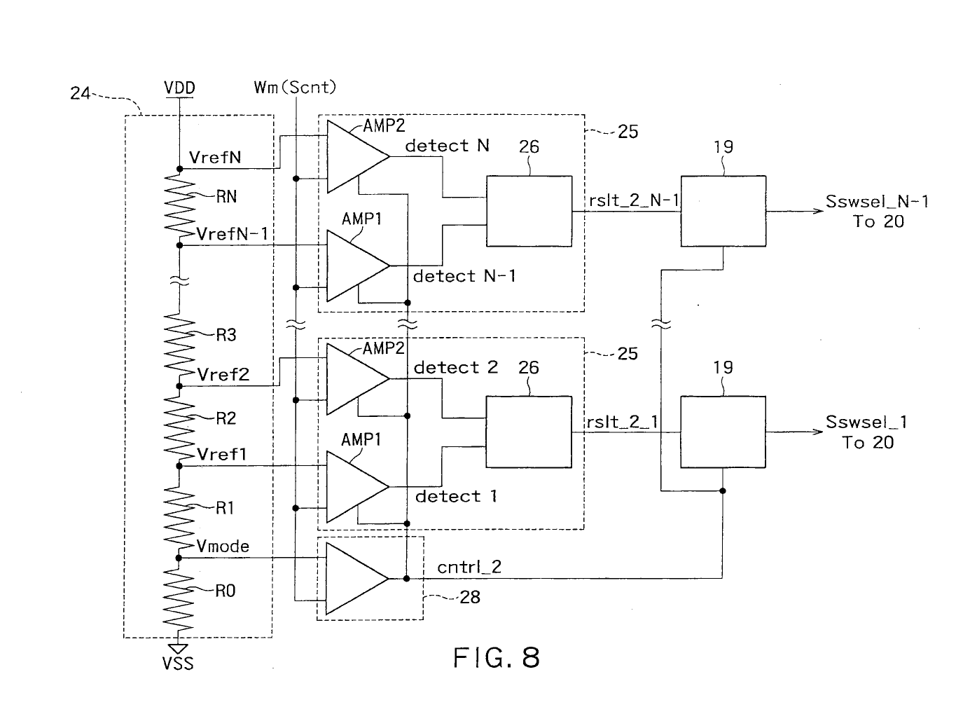

FIG. 8 is a block diagram showing a configuration example of the selection control circuit 10 in a case where one monitor unit MU includes a plurality of elements 30 and a plurality of switches 20. Each of the numbers of the elements 30 and the switches 20 is designated as N−1.

In this case, the signal generator 24 includes resistors R0 to RN to generate switch reference signals Vref1 to VrefN. The resistors R0 to RN are connected in series between VDD and VSS. N−1 determination part 25 and N−1 determination-result storage part 19 are provided while respectively corresponding to the switch 20 or the element 30. Only one mode comparator 28 is provided, and the mode signal cntrl_2 is commonly used for N−1 pairs of operation amplifiers (AMP1 and AMP2) and N−1 determination-result storage parts 19.

For example, when the control voltage Vcnt is in a range between the switch reference voltages Vref1 and Vref2, a detection result rslt_2_1 and a switch selection signal Sswsel_1 shown in FIG. 8 are raised and the switch 20 corresponding to the switch selection signal Sswsel_1 becomes conductive. When the control voltage Vcnt is in a range between the switch reference voltages Vref2 and Vref3, a switch selection signal Sswsel_2 (not shown) is raised and the switch 20 corresponding to the switch selection signal Sswsel_2 becomes conductive. Similarly, when the control voltage Vcnt is in a range between a switch reference voltage VrefN−1 and the switch reference voltage VrefN, a determination result rslt_2_N−1 and a switch selection signal Sswsel_N−1 are raised, and the switch 20 corresponding to the switch selection signal Sswsel_N−1 becomes conductive.

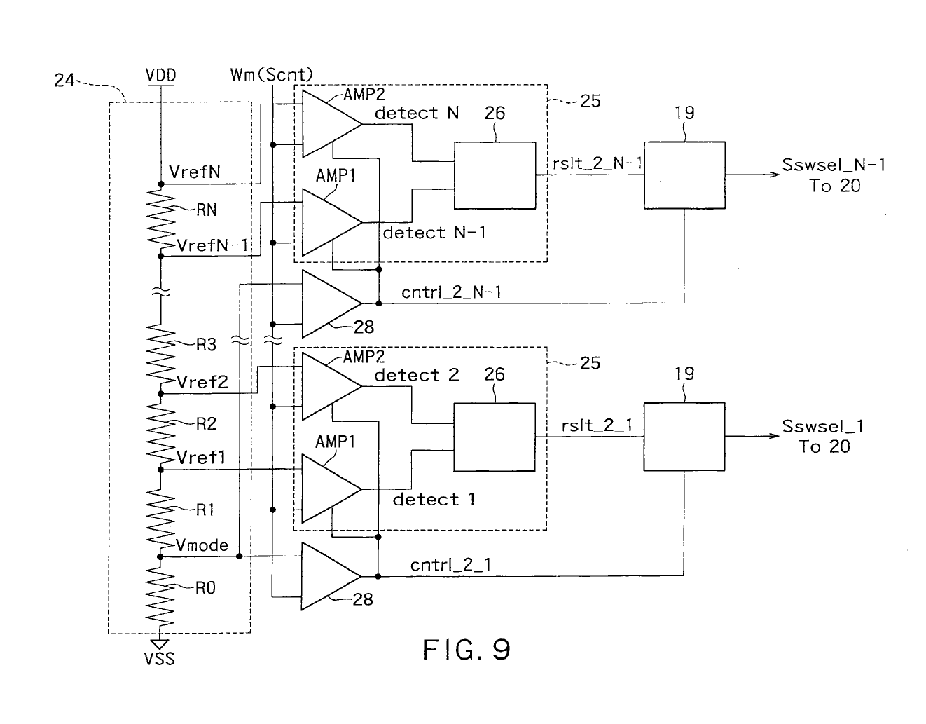

FIG. 9 is a block diagram showing another configuration example of the selection control circuit 10 in a case where one monitor unit MU includes a plurality of elements 30 and a plurality of switches 20. Each of the numbers of the elements 30 and the switches 20 is designated as N−1.

The selection control circuit 10 shown in FIG. 9 is different from the selection control circuit 10 shown in FIG. 8 in that N−1 mode comparators 28 are provided. Other configurations of the selection control circuit 10 shown in FIG. 9 can be identical to corresponding ones of the selection control circuit 10 shown in FIG. 8.

The mode reference signal Vmode and the control signal Scnt are commonly input to N−1 mode comparators 28. Each of the mode comparators 28 compares the mode reference signal Vmode and the control signal Scnt. Other operations of the selection control circuit 10 shown in FIG. 9 can be identical to corresponding ones of the selection control circuit 10 shown in FIG. 8.

By using the selection control circuit 10 shown in FIG. 8 or FIG. 9, even if one monitor unit MU includes a plurality of elements 30 and a plurality of switches 20, the semiconductor device 1 according to the present modification can obtain the effects of the second embodiment.

In the above embodiments, it has been explained that the control signal Scnt is a pulse signal of a positive voltage or an analog signal of a positive voltage; however, the control signal Scnt can be a pulse signal of a negative voltage or an analog signal of a negative voltage. Furthermore, the logic of signals such as the mode signals cntrl_1 and cntrl_2, the detection results rslt_1 and rslt_2, the switch selection signal Sswsel, and the like can be inverted. In the case where the logic is inverted, the switch 20 becomes conductive when the switch selection signal Sswsel is logical low.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising a plurality of monitor units monitoring characteristics of an element, wherein
each of the monitor units comprises:
the element;
a control/monitor node transmitting a control signal for controlling the monitor units, and transmitting a characteristic signal for indicating electrical characteristics of the element;
a switch connected between the element and the control/monitor node; and
a selection controller selectively controlling the switch upon reception of the control signal, wherein
a wire of the control/monitor node of the plurality of monitor units is commonalized.

2. The device of claim 1, wherein the selection controller of each of the monitor units stores therein identification information for identifying the monitor units or the switches in the monitor units, and
when the identification information matches selection information included in the control signal and selecting the switch, the selection controller causes the switch corresponding to the selection controller to be conductive, and outputs the characteristic signal via the control/monitor node.

3. The device of claim 2, wherein
the selection controller comprises:
a control-signal storage part storing therein the control signal;
an identification-information storage part storing therein the identification information;
a determination part determining whether the selection information and the identification information match each other; and
a determination-result storage part storing a determination result determined by the determination part and controlling the switch according to the determination result.

4. The device of claim 3, wherein
the control signal includes a monitor mode signal for indicating that the device is in a mode in which characteristics of the element are monitored, and
the determination-result storage part is configured to output the switch control signal when the monitor mode signal is indicating that the device is in a monitor mode.

5. The device of claim 2, wherein
when one of the monitor units comprises a plurality of the elements and a plurality of the switches corresponding to the plurality of elements,
the identification-information storage part stores therein plural pieces of the identification information respectively corresponding to the switches,
the determination part respectively compares the selection information to the plural pieces of the identification information, and
the determination-result storage part stores therein a plurality of the determination results corresponding to the switches and causes one of the switches having been selected according to the determination results to be conductive.

6. The device of claim 3, wherein
when one of the monitor units comprises a plurality of the elements and a plurality of the switches corresponding to the plurality of elements,
the identification-information storage part stores therein plural pieces of the identification information respectively corresponding to the switches,
the determination part respectively compares the selection information to the plural pieces of the identification information, and
the determination-result storage part stores therein a plurality of the determination results corresponding to the switches and causes one of the switches having been selected according to the determination results to be conductive.

7. The device of claim 4, wherein
when one of the monitor units comprises a plurality of the elements and a plurality of the switches corresponding to the plurality of elements,
the identification-information storage part stores therein plural pieces of the identification information respectively corresponding to the switches,
the determination part respectively compares the selection information to the plural pieces of the identification information, and
the determination-result storage part stores therein a plurality of the determination results corresponding to the switches and causes one of the switches having been selected according to the determination results to be conductive.

8. The device of claim 2, wherein the selection information and the identification signal are a digital value, respectively.

9. The device of claim 1, wherein the selection controller of each of the monitor units is configured to generate a switch reference signal corresponding to the monitor units or the switch in the monitor units, to compare the control signal and the switch reference signal, to cause the switch to be conductive according to a voltage level of the control signal, and to output the characteristic signal via the control/monitor node.

10. The device of claim 9, wherein
the selection controller comprises:
a reference-signal generator generating the switch reference signal;
a determination part comparing the control signal and the switch reference signal; and
a determination-result storage part outputting a switch control signal controlling the switch according to a voltage level of the control signal.

11. The device of claim 10, wherein
the reference-signal generator further generates a mode reference signal for setting the selection controller to be a monitor mode,
the selection controller comprises a mode comparator comparing the control signal and the mode reference signal, and
the mode comparator activates the determination part and the determination-result storage part according to a voltage level of the control signal.

12. The device of claim 11, wherein
the mode reference signal has a voltage lower than that of the switch reference signal, and
the selection controller enters a monitor mode when a voltage of the control signal exceeds a voltage level of the mode reference signal, and activates the determination part and the determination-result storage part.

13. The device of claim 10, wherein
when one of the monitor units comprises a plurality of the elements and a plurality of the switches corresponding to the plurality of elements,
the reference-signal generator generates a plurality of the switch reference signals including a plurality of voltage levels respectively corresponding to the switches,
the determination part compares a voltage of the control signal and a voltage level of each of the switch reference signals and outputs a determination result according to the voltage of the control signal, and
the determination-result storage part stores therein a plurality of the determination results corresponding to the switches and causes one of the switches having been selected based on the determination results to be conductive.

14. The device of claim 11, wherein
when one of the monitor units comprises a plurality of the elements and a plurality of the switches corresponding to the plurality of elements,
the reference-signal generator generates a plurality of the switch reference signals including a plurality of voltage levels respectively corresponding to the switches,
the determination part compares a voltage of the control signal and a voltage level of each of the switch reference signals and outputs a determination result according to the voltage of the control signal, and
the determination-result storage part stores therein a plurality of the determination results corresponding to the switches and causes one of the switches having been selected based on the determination results to be conductive.

15. The device of claim 12, wherein
when one of the monitor units comprises a plurality of the elements and a plurality of the switches corresponding to the plurality of elements,
the reference-signal generator generates a plurality of the switch reference signals including a plurality of voltage levels respectively corresponding to the switches,
the determination part compares a voltage of the control signal and a voltage level of each of the switch reference signals and outputs a determination result according to the voltage of the control signal, and
the determination-result storage part stores therein a plurality of the determination results corresponding to the switches and causes one of the switches having been selected based on the determination results to be conductive.

16. The device of claim 9, wherein the control signal and the switch reference signal are an analog value, respectively.

17. The device of claim 1, wherein the plurality of monitor units are arranged in one semiconductor chip.
